(19) United States
(12) Patent Application Publication
(10) Pub. No.: US 2021/0040602 A1
(43) Pub. Date: Feb. 11, 2021

(54) C-CONTAINING SPUTTERING TARGET AND METHOD FOR PRODUCING SAME

(71) Applicant: TANAKA KIKINZOKU KOGYO K.K., Tokyo (JP)

(72) Inventors: Takamichi Yamamoto, Ibaraki (JP); Masahiro Nishiura, Ibaraki (JP); Kenta Kurose, Ibaraki (JP); Hironori Kobayashi, Ibaraki (JP); Takanobu Miyashita, Ibaraki (JP); Masahumi Nakano, Ibaraki (JP)

(21) Appl. No.: 17/044,687

(22) PCT Filed: Apr. 22, 2019
(86) PCT No.: PCT/JP2019/016922

§ 371 Date: Oct. 1, 2020

(30) Foreign Application Priority Data
Apr. 27, 2018 (JP) 2018-086305

(51) Int. Cl. C23C 14/34; C22C 5/04; C22C 1/05; C22C 38/00

(52) U.S. Cl. CPC C23C 14/3414; C22C 38/00; C22C 1/05; C22C 5/04

(57) ABSTRACT

A sputtering target with suppressed aggregation of C particles and reduced generation of particles is provided.

A C-containing sputtering target comprises Pt, C, and one or more selected from Fe and Co, where in a particle size distribution of a dissolution residue of the sputtering target, 90 percentile of the particle diameter based on the volume, D90 is 20.0 μm or less, and particle size of less than 1.0 μm accounts for 40% or less in cumulative volume distribution.

### TECHNICAL FIELD

The present invention relates to a C-containing sputtering target and a production method therefor and particularly relates to a C-containing sputtering target comprising Pt, C (carbon), and either Fe or Co and a production method therefor.

### BACKGROUND ART

The present inventors have proposed an FePt-C-based sputtering target that can alone form an FePt-C-based thin film having a high carbon content without using a plurality of targets (Patent Literature (PTL) 1, PTL 2, PTL 3).

PTL 1 discloses an FePt-C-based sputtering target that contains Fe, Pt, and C and has a mutually dispersed structure of: an FePt-based alloy phase containing 40 to 60 at % of Pt with the balance being Fe and incidental impurities; and a C phase containing C and incidental impurities, where C content is 21 to 70 at % relative to the target. The FePt-C-based sputtering target of PTL 1 is produced by mixing atomized FePt alloy powder with C powder having an average particle size of 20 to 100 nm in a ball mill, and sintering the prepared mixed powder, where the average size of the C phase is 0.60 μm or less.

PTL 2 discloses an FePt-C-based sputtering target having a structure in which C primary particles containing incidental impurities are dispersed without being in contact with each other in an FePt alloy phase containing 33 at % or more and 60 at % or less of Pt with the balance being Fe and incidental impurities, where: the C primary particles have an average particle size of 1 μm or more and 30 μm or less; and a surface area of C covered with the FePt-based alloy phase is 80% or more based on the total surface area of C. The FePt-C-based sputtering target of PTL 2 is produced by: mixing Fe atomized powder that has passed through a sieve having an opening size of 20 μm or Fe powder having an average particle size of 10 μm, Pt powder having an average particle size of 1 μm, and amorphous carbon having an average particle size of 8 μm in a tumbler mixer for 15 minutes; and sintering the prepared mixed powder. Here, the tumbler mixer is an apparatus for mixing powders by rotating a mixing container held at an angle (commercially available, for example, as a tumbler mixer from Eishin Co., Ltd. and Mazemazeman® from Misugi Co., Ltd.).

PTL 3 discloses an FePt-C-based sputtering target having a structure in which a non-spherical C phase substantially consisting of C is dispersed in an FePt-based alloy phase containing 33 mol % or more and 60 mol % or less of Pt with the balance substantially being Fe. The FePt-C-based sputtering target of PTL 3 is produced by: mixing non-spherical C powder with FePt alloy powder obtained by an atomization method or each Pt and Fe powder in a mixer using balls at 300 rpm for 30 minutes; and sintering the prepared mixed powder.

Moreover, there has been proposed a sputtering target prepared by mixing and pulverizing raw material powder having average particle sizes of 0.5 μm or more and 10 μm or less in a ball mill for 4 hours, hot pressing the resulting mixed powder, and subjecting the obtained sintered compact to hot isostatic pressing, where C grains with a mean area of 4 μm² or less are finely and uniformly dispersed in the matrix alloy (PTL 4).

Further, there has been proposed a sputtering target obtained by mixing flat or tabular FePt-based alloy powder with flat or tabular C powder (flaked graphite powder) having an average particle size of 15 μm in a mortar and subjecting to hot pressing under uniaxial pressure, where a C phase is dispersed while aligning in a specific direction (PTL 5).

### CITATION LIST

### Patent Literature

PTL 1: Japanese Unexamined Patent Application Publication No. 2012-214874

PTL 2: Japanese Patent No. 5965539

PTL 3: WO 2017/154741A1

PTL 4: Japanese Patent No. 5290468

PTL 5: Japanese Patent No. 5457615

### SUMMARY OF INVENTION

### Technical Problem

There have been proposed, for example, a method of gently mixing coarse C particles to suppress excessive pulverization of the C particles, a method of subjecting to hot isostatic pressing to suppress generation of particles due to release of fine C particles, and a method of uniaxially pressing a mixture of flat alloy powder and C powder. However, according to such conventional methods, it was impossible to break up aggregates of C particles. Consequently, a portion of aggregated C particles exists inside a target and acts as a starting point for particle generation. An object of the present invention is to provide a sputtering target with suppressed aggregation of C particles and reduced generation of particles.

### Solution to Problem

As a result of intensive studies, the present inventors found that C particles pulverized into less than 1 μm through vigorous mixing adversely affect generation of particles. Moreover, the present inventors found that gentle mixing, which is comparable to conventional gentle mixing, for a prolonged time by a mixing method that enables more uniform mixing than conventional gentle mixing suppresses formation of C particles of less than 1 μm, breaks up aggregates of C particles, and suppresses formation of a portion of aggregated C particles, thereby completing a sputtering target that can better suppress particle generation than ever before.

Specific embodiments of the present invention are as follows.

[1] A C-containing sputtering target comprising Pt, C, and one or more selected from Fe and Co, where in a particle size distribution of a dissolution residue of the sputtering target, 90 percentile of the particle diameter based on the volume, D90 is 20.0 μm or less, and particle size of less than 1.0 μm accounts for 40% or less in a cumulative volume distribution.

[2] The C-containing sputtering target according to [1] above, where the D90 is 5.0 μm or more and 20.0 μm or less.

[3] The C-containing sputtering target according to [1] or [2] above, where further in the particle size distribution of the dissolution residue of the sputtering target, 50 percentile of the particle diameter based on the volume, D50 is 2.0 μm or more and 7.0 μm or less.

[4] The C-containing sputtering target according to any one of [1] to [3] above, where further in the particle size distribution of the dissolution residue of the sputtering target, 10 percentile of the particle diameter based on the volume, D10 is 0.5 μm or more and 2.0 μm or less.

[5] The C-containing sputtering target according to any one of [1] to [4] above, comprising 5 mol % or more and 55 mol % or less of Pt and 10 mol % or more and 60 mol % or less of C, with the balance being one or more selected from Fe and Co as well as incidental impurities.

[6] The C-containing sputtering target according to [5] above, further comprising, in total, more than 0 mol % and 20 mol % or less of one or more selected from Ag, Au, B, Cr, Cu, Ge, Ir, Ni, Pd, Rh, and Ru.

[7] The C-containing sputtering target according to [5] or [6] above, further comprising, in total, more than 0 mol % and 20 mol % or less of a nonmagnetic material excluding C.

[8] The C-containing sputtering target according to [7] above, where the nonmagnetic material is one or more selected from Si oxide, Ti oxide, Ta oxide; B nitride, Ti nitride, and Ta nitride.

[9] A production method for the C-containing sputtering target according to any one of [1] to [8] above, comprising: mixing a C powder with at least one selected from metal powders and an alloy powder by a mixing apparatus having a three-dimensional motion mechanism for rotating in a vertical direction and a horizontal direction to prepare a mixture; and sintering the mixture.

[10] The production method for the C-containing sputtering target according to [9] above, where the mixing of a C powder with at least one selected from metal powders and an alloy powder is performed at 10 rpm or more and 50 rpm or less for 20 hours or more.

### Advantageous Effects of Invention

The C-containing sputtering target comprising Pt, C, and one or more selected from Fe and Co according to the present invention has, in a particle size distribution of a dissolution residue, 90 percentile of the particle diameter based on the volume, D90 of 20.0 μm or less and particle size of less than 1.0 μm of 40% or less in a cumulative volume distribution. As a result, the sputtering target contains a few extremely fine particles and exhibits suppressed generation of aggregates through breaking up of fine particle aggregates, thereby reducing generation of particles. The C-containing sputtering target of the present invention can be suitably used for manufacture of magnetic recording media.

By performing mixing gentler than conventional mixing methods by a ball mill, a pot mill, a medium stirring mill, and the like for a prolonged time, the production method for a C-containing sputtering target of the present invention can suppress excessive pulverization of C particles during mixing while achieving uniform and fine mixing of C particles. As a result, it is possible to reduce generation of particles during film formation.

### BRIEF DESCRIPTION OF DRAWINGS

FIG. 1 is a graph showing a measured particle size distribution of a dissolution residue of a sputtering target obtained in Example 1.

FIG. 2 is a photograph of a scanning electron microscope (SEM) (1,000×) of the dissolution residue of the sputtering target obtained in Example 1.

FIG. 3 is a photograph of a scanning electron microscope (SEM) (5,000×) of the dissolution residue of the sputtering target obtained in Example 1.

FIG. 4 is a photograph of a graph showing a measured particle size distribution of a dissolution residue of a sputtering target obtained in Comparative Example 2.

FIG. 5 is a photograph of a scanning electron microscope (SEM) (1,000×) of the dissolution residue of the sputtering target obtained in Comparative Example 2.

FIG. 6 is a photograph of a scanning electron microscope (SEM) (5,000×) of the dissolution residue of the sputtering target obtained in Comparative Example 2.

FIG. 7 is a graph showing a measured particle size distribution of a dissolution residue of a sputtering target obtained in Comparative Example 3.

FIG. 8 is a photograph of a scanning electron microscope (SEM) (1,000×) of the dissolution residue of the sputtering target obtained in Comparative Example 3.

FIG. 9 is a photograph of a scanning electron microscope (SEM) (5,000×) of the dissolution residue of the sputtering target obtained in Comparative Example 3.

### DESCRIPTION OF EMBODIMENTS

The C-containing sputtering target of the present invention comprising Pt, C, and either Fe or Co is characterized in that in a particle size distribution of a dissolution residue of the sputtering target, 90 percentile of the particle diameter based on the volume, D90 is 20.0 μm or less and particle size of less than 1.0 μm accounts for 40% or less in cumulative volume distribution.

D90 is preferably 5.0 μm or more and 20.0 μm or less.

Moreover, in the particle size distribution of the dissolution residue of the sputtering target, 50 percentile of the particle diameter based on the volume, D50 is preferably 2.0 μm or more and 7.0 μm or less.

Further, in the particle size distribution of the dissolution residue of the sputtering target, 10 percentile of the particle diameter based on the volume, D10 is preferably 0.5 μm or more and 2.0 μm or less.

In the present invention, the “dissolution residue of a sputtering target” means a solid component excluding metals from the components of the sputtering target or a residue obtained by dissolving in aqua regia [3:1 mixture of concentrated hydrochloric acid (special grade) and concentrated nitric acid (special grade)], in nitric acid and aqua regia in the case of a sputtering target containing Ag, or in hydrochloric acid and aqua regia in the case of a sputtering target containing Cr. Such a residue primarily contains C (carbon) but also contains an oxide or a nitride when a sputtering target contains such an oxide or a nitride. These dissolution residues are particles of nonmagnetic materials, which cause particle generation during sputtering.

In the present invention, a particle size distribution of a “dissolution residue of a sputtering target” is measured by the following method.

Pulverized powder of a sputtering target is put through a stack of two sieves having opening sizes of 500 μm and 106 μm to collect powder of 106 μm or more and less than 500 μm. The collected powder is immersed for 1 hour in aqua regia heated on a hot plate at 200° C. to yield a residue solution. This procedure is repeated three times. The resulting residue-containing liquid is filtered through a 5A filter paper, the residue on the filter paper is washed with pure water, the water including the residue is filtered through the 5A filter paper again, and the filter paper is spread and dried on a hot plate at 80° C. To a 100 mL beaker, 30 mL of pure water and 0.15 g of a surfactant (neutral detergent) are fed, and 0.15 g of the obtained residue powder weighed out is dispersed in the beaker by an ultrasonic homogenizer at 200 μA to 300 μA for 5 minutes. The obtained sample dispersion is measured by a particle size analyzer.

When a sputtering target contains Ag (silver) as a metal component, since Ag does not dissolve in aqua regia, powder is first immersed in nitric acid to dissolve Ag and then the obtained residue is immersed in aqua regia. Similarly, when a sputtering target contains Cr (chromium) as a metal component, since Cr does not dissolve in aqua regia, powder is first immersed in hydrochloric acid to dissolve Cr and then the obtained residue is immersed in aqua regia.

The C-containing sputtering target of the present invention comprises 5 mol % or more and 55 mol % or less and preferably 10 mol % or more and 50 mol % or less of Pt and 10 mol % or more and 60 mol % or less and preferably 15 mol % or more and 55 mol % or less of C, with the balance being one or more selected from Fe and Co as well as incidental impurities. Hereinafter, for convenience, the C-containing sputtering target of the present invention is also abbreviated to “(Fe/Co)-Pt-C-based target” and the alloy component to “(Fe/Co)-Pt-based alloy” in some cases. Here, the expression “(Fe/Co)” indicates at least one selected from Fe and Co, in other words, Fe, Co, or an FeCo alloy. Within the above-mentioned ranges, C can well act as a grain boundary material within a sputtered film and isolate (Fe/Co)-Pt-based alloy grains. As a result, it is possible to satisfactorily maintain the magnetic characteristics of the (Fe/Co)-Pt-based alloy.

The C-containing sputtering target of the present invention may further comprise, as metal components in total, more than 0 mol % and 20 mol % or less and preferably more than 0 mol % and 15 mol % or less of one or more selected from Ag, Au, B, Cr, Cu, Ge, Ir, Ni, Pd, Rh, and Ru. Within these ranges, it is possible to satisfactorily maintain the magnetic characteristics of the (Fe/Co)-Pt-based alloy.

Moreover, the C-containing sputtering target of the present invention may comprise, in total, more than 0 mol % and 20 mol % or less and preferably more than 0 mol % and 10 mol % or less of a nonmagnetic material excluding C. Preferable examples of the nonmagnetic material include one or more selected from Si oxide, Ti oxide, Ta oxide; B nitride, Ti nitride, and Ta nitride. As the oxide, SiO, SiO₂, Si₃O₂, TiO, TiO₂, Ti₂O₃, and Ta₂O₅ are preferable, and SiO₂, TiO₂, and Ta₂O₅ are more preferable. As the nitride, BN, TiN, Ta₂N, and TaN are preferable, and BN, TiN, and TaN are more preferable. The nonmagnetic material can well act as a grain boundary material, together with C, within a sputtered film and isolate (Fe/Co)-Pt-based alloy grains, thereby satisfactorily maintaining the magnetic characteristics of the (Fe/Co)-Pt-based alloy.

The C-containing sputtering target of the present invention can be produced by a production method characterized by comprising: mixing metal powders with a C powder by a mixing apparatus having a three-dimensional motion mechanism for rotating in a vertical direction and a horizontal direction to prepare a mixture; and sintering the mixture. The three-dimensional motion for rotating in the vertical direction and the horizontal direction means a motion for reversing the top and bottom as well as the left and right of the mixing apparatus and is also referred to as shaking mechanism. Specifically, a shaking mixer can be suitably employed. The mixing of metal powders with a C powder by a mixing apparatus having a three-dimensional motion mechanism for rotating in a vertical direction and a horizontal direction is performed as mixing by rotating a mixing container in the vertical direction and the horizontal direction at 10 rpm or more and 50 rpm or less and preferably 20 rpm or more and 40 rpm or less for a prolonged time of preferably 20 hours or more, more preferably 24 hours or more, and further preferably 48 hours or more; and preferably 96 hours or less and more preferably 72 hours or less. Mixing for a prolonged time under mild conditions within the above-mentioned ranges pulverizes C particles (and oxide particles and BN particles, if present) without excessive pulverization into fine particles of less than 1 μm while breaking up aggregates formed from pulverized fine particles. Consequently, it is possible to obtain mixed powder having a homogenous particle size distribution. To obtain mixed powder having a further homogeneous particle size distribution, it is preferable to use powder separated through a sieve having an opening size of 300 μm. An (Fe/Co)-Pt-C-based target can be produced by sintering the obtained mixed powder at a sintering temperature of 600° C. or higher and 1,000° C. or lower and preferably 700° C. or higher and 900° C. or lower and a sintering pressure of 30 MPa or higher and 200 MPa or lower and preferably 50 MPa or higher and 100 MPa or lower.

### EXAMPLES

Hereinafter, the present invention will be specifically described by means of Examples. However, the present invention is not limited to these Examples.

In each Example and Comparative Example, the measurement method for particle size distribution of a dissolution residue of a sputtering target and the assessment methods for relative density and particles are as follows.

[Particle Size Distribution of Dissolution Residue]

A sputtering target is cut into about 4 mm-square and pulverized in a crusher (Wonder Blender from Osaka Chemical Co., Ltd.) for 30 seconds. The pulverized powder (100 g) is separated on sieves having opening sizes of 106 μm and 500 μm set above a pan by shaking with a sieve shaker for 1 minute to collect powder (30 g) that has passed through the 500 μm sieve and remains on the 106 μm sieve. The collected powder is immersed in aqua regia (100 mL: 3:1 mixture of special grade hydrochloric acid: product No. 18078-00 and special grade nitric acid (specific gravity of 1.38): product No. 28163-00 from Kanto Chemical Co., Inc.) heated on a hot plate at 200° C. until reactions are terminated. Subsequently, a residue is immersed in new aqua regia. The same procedure is repeated three times. The obtained residue liquid is filtered through a 5A filter paper (pore size of 7 μm), a residue on the filter paper is washed with pure water while pouring into a beaker, the water including the residue is filtered through the 5A filter paper again, and the filter paper is spread and dried on a hot plate at 80° C. To a 100 mL beaker, 30 mL of water and 0.15 g of a surfactant (First Fresh (trade name) neutral dishwashing detergent from Daiichisekken, Co., Ltd.) are fed, and 0.15 g of the obtained residue powder weighed out is dispersed in the beaker by an ultrasonic homogenizer (US-150T from Nihon Seiki Kaisha Ltd.) at V-LEVEL adjusted to 200 μA to 300 μA for 5 minutes. The obtained sample dispersion is measured by a particle size analyzer (MT-3300EXII from MicrotracBEL Corp.) under the conditions shown in Table 1 below. To increase analytical precision, when 10 percentile of the particle diameter based on the volume (D10), 50 percentile of the particle diameter based on the volume (D50), and 90 percentile of the particle diameter based on the volume (D90) are each measured twice and confirmed to fall outside error ranges of ±0.1 μm in the case of 0 μm or μore and less than 10 μm, ±0.2 μm in the case of 10 μm or more and less than 40 μm, and ±1 μm in the case of 40 μm or more, the measurement is performed again. On the data analysis window of the particle size analyzer, “1 μm pass” (cumulative volume % value of particles passing through 1 μm sieve) at “size %” is regarded as “cumulative volume % of less than 1 μm.”

TABLE 1

| Particle information | Transparency | Absorbing |
|---|---|---|
| Fluid information | Carrier fluid | Water |
| | Fluid refractive index | 1.333 |
| Timing | SetZero time | 30 |
| | Run time | 30 |
| | Number of runs | 2 |
| Analysis options | Analysis mode | MT3000 |
| Perspective | Progression | Standard |
| | Distribution | Volume |
| Sample delivery | Sampling | SDC |
| | Number of rinses | 3 |
| | Flow rate (%) | 60 |
| | Deaeration cycles | 3 |

[Relative Density]

The relative density is measured by the Archimedes method using pure water as a replacement liquid. First, an actual density (g/cm³) is determined by: measuring the mass of a test piece; measuring a buoyant force (=the volume of the test piece) when the test piece floating on the replacement liquid is fully submerged; and dividing the mass (g) of the test piece by the volume (cm³) of the test piece. The ratio of the actual density to a theoretical density calculated on the basis of the composition of a sintered compact (actual density/theoretical density) is a relative density.

[Assessment of Particles]

A sputtering target (diameter of 153 mm, thickness of 2 mm) bonded by using indium to a Cu backing plate (diameter of 161 mm, thickness of 4 mm) is fixed to a magnetron sputtering apparatus. After discharging at an argon gas pressure of 1 Pa and an output of 500 W for 2 hours, a film is formed on a glass substrate at an argon gas pressure of 1 Pa and an output of 500 W for 2 seconds, and the number of particles is counted by a particle counter.

### Example 1

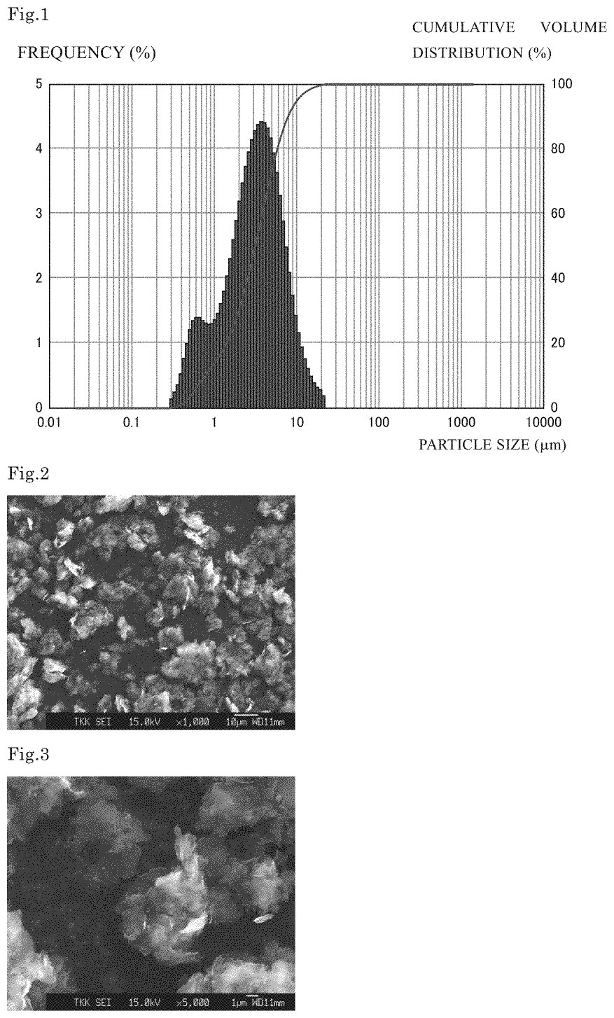

To achieve (Fe-50Pt)-40C (mol %) [30Fe-30Pt-40C], 146.44 g of Fe powder (average particle size of 7 μm), 511.56 g of Pt powder (average particle size of 1 μm), and 41.99 g of C powder (average particle size of 20 μm), together with 2 kg of zirconia balls, were placed in a stainless steel container and mixed at 32 rpm for 48 hours by using a shaking mixer having a three-dimensional motion mechanism for rotating in the vertical and horizontal directions. After mixing, the resulting powder was separated on a sieve having an opening size of 300 μm, and the powder that had passed through the sieve was sintered under conditions of a sintering pressure of 66 MPa, a sintering temperature of 900° C., and a holding time of 1 hour. The resulting sintered compact was processed into a diameter of 153 mm and a thickness of 2 mm to obtain a sputtering target and subjected to the assessment of particles. Subsequently, a sample was cut out from the sputtering target and subjected to the measurement of relative density and particle size distribution of a dissolution residue. The results are shown in Table 2. FIG. 1 shows the measured particle size distribution of a dissolution residue, and FIGS. 2 and 3 show photographs of a scanning electron microscope (SEM) (1,000× and 5,000×) of the dissolution residue.

### Example 2

A sputtering target was obtained in the same manner as Example 1 except for changing the mixing time using a shaking mixer having a three-dimensional motion mechanism for rotating in the vertical and horizontal directions to 24 hours and was subjected to the assessment of particles and the measurement of relative density and particle size distribution of a dissolution residue. The results are shown in Table 2.

### Example 3

A sputtering target was obtained in the same manner as Example 1 except for changing to C powder having an average particle size of 10 μm as a raw material and was subjected to the assessment of particles and the measurement of relative density and particle size distribution of a dissolution residue. The results are shown in Table 2.

### Example 4

To achieve (Fe-45Pt-10Ag)-40C (mol %) [27Fe-27Pt-6Ag-40C], 129.74 g of Fe powder (average particle size of 7 μm), 453.22 g of Pt powder (average particle size of 1 μm), 55.69 g of Ag powder (average particle size of 10 μm), and 41.34 g of C powder (average particle size of 20 μm), together with 2 kg of zirconia balls, were placed in a stainless steel container and mixed at 32 rpm for 48 hours by using a shaking mixer having a three-dimensional motion mechanism for rotating in the vertical and horizontal directions. After mixing, the resulting powder was separated on a sieve having an opening size of 300 μm, and the powder that had passed through the sieve was sintered under conditions of a sintering pressure of 66 MPa, a sintering temperature of 900° C., and a holding time of 1 hour. The resulting sintered compact was processed into a diameter of 153 mm and a thickness of 2 mm to obtain a sputtering target and subjected to the assessment of particles and the measurement of relative density and particle size distribution of a dissolution residue. The results are shown in Table 2.

### Example 5

To achieve (Fe-52Pt)-30C-6SiO₂ (mol %) [30.72Fe-33.28Pt-30C-6SiO₂], 122.97 g of Fe powder (average particle size of 7 μm), 465.36 g of Pt powder (average particle size of 1 μm), 25.83 g of C powder (average particle size of 20 μm), and 25.84 g of SiO₂ powder (average particle size of 0.6 μm), together with 2 kg of zirconia balls, were placed in a stainless steel container and mixed at 32 rpm for 48 hours by using a shaking mixer having a three-dimensional motion mechanism for rotating in the vertical and horizontal directions. After mixing, the resulting powder was separated on a sieve having an opening size of 300 μm, and the powder that had passed through the sieve was sintered under conditions of a sintering pressure of 66 MPa, a sintering temperature of 900° C., and a holding time of 1 hour. The resulting sintered compact was processed into a diameter of 153 mm and a thickness of 2 mm to obtain a sputtering target and subjected to the assessment of particles and the measurement of relative density and particle size distribution of a dissolution residue. The results are shown in Table 2.

### Example 6

To achieve (Fe-45Pt)-30C-5BN (mol %) [35.75Fe-29.25Pt-30C-5BN], 163.39 g of Fe powder (average particle size of 7 μm), 466.97 g of Pt powder (average particle size of 1 μm), 29.49 g of C powder (average particle size of 20 μm), and 10.16 g of BN powder (average particle size of 10 μm), together with 2 kg of zirconia balls, were placed in a stainless steel container and mixed at 32 rpm for 48 hours by using a shaking mixer having a three-dimensional motion mechanism for rotating in the vertical and horizontal directions. After mixing, the resulting powder was separated on a sieve having an opening size of 300 μm, and the powder that had passed through the sieve was sintered under conditions of a sintering pressure of 66 MPa, a sintering temperature of 900° C., and a holding time of 1 hour. The resulting sintered compact was processed into a diameter of 153 mm and a thickness of 2 mm to obtain a sputtering target and subjected to the assessment of particles and the measurement of relative density and particle size distribution of a dissolution residue. The results are shown in Table 2.

### Example 7

To achieve (Co-5Cr-23Pt)-40C (mol %) [43.2Co-3Cr-13.8Pt-40C], 247.03 g of Co powder (average particle size of 3 μm), 261.22 g of Pt powder (average particle size of 1 μm), 15.14 g of Cr powder (average particle size of 20 μm), and 46.62 g of C powder (average particle size of 20 μm), together with 2 kg of zirconia balls, were placed in a stainless steel container and mixed at 32 rpm for 48 hours by using a shaking mixer having a three-dimensional motion mechanism for rotating in the vertical and horizontal directions. After mixing, the resulting powder was separated on a sieve having an opening size of 300 μm, and the powder that had passed through the sieve was sintered under conditions of a sintering pressure of 66 MPa, a sintering temperature of 900° C., and a holding time of 1 hour. The resulting sintered compact was processed into a diameter of 153 mm and a thickness of 2 mm to obtain a sputtering target and subjected to the assessment of particles and the measurement of relative density and particle size distribution of a dissolution residue. The results are shown in Table 2.

### Example 8

To achieve (Co-12Cr-18Pt)-20C (mol %) [56Co-9.6Cr-14.4Pt-20C], 308.40 g of Co powder (average particle size of 3 μm), 262.51 g of Pt powder (average particle size of 1 μm), 46.65 g of Cr powder (average particle size of 20 um), and 22.45 g of C powder (average particle size of 20 μm), together with 2 kg of zirconia balls, were placed in a stainless steel container and mixed at 32 rpm for 48 hours by using a shaking mixer having a three-dimensional motion mechanism for rotating in the vertical and horizontal directions. After mixing, the resulting powder was separated on a sieve having an opening size of 300 μm, and the powder that had passed through the sieve was sintered under conditions of a sintering pressure of 66 MPa, a sintering temperature of 900° C., and a holding time of 1 hour. The resulting sintered compact was processed into a diameter of 153 mm and a thickness of 2 mm to obtain a sputtering target and subjected to the assessment of particles and the measurement of relative density and particle size distribution of a dissolution residue. The results are shown in Table 2.

### Example 9

To achieve (Fe-30Co-30Pt)-50C (mol %) [20Fe-15Co-15Pt-50C], 122.41 g of Fe powder (average particle size of 7 μm), 96.89 g of Co powder (average particle size of 3 μm), 320.71 g of Pt powder (average particle size of 1 um), and 65.82 g of C powder (average particle size of 20 um), together with 2 kg of zirconia balls, were placed in a stainless steel container and mixed at 32 rpm for 48 hours by using a shaking mixer having a three-dimensional motion mechanism for rotating in the vertical and horizontal directions. After mixing, the resulting powder was separated on a sieve having an opening size of 300 μm, and the powder that had passed through the sieve was sintered under conditions of a sintering pressure of 66 MPa, a sintering temperature of 900° C., and a holding time of 1 hour. The obtained sintered compact was processed into a diameter of 153 mm and a thickness of 2 mm to obtain a sputtering target and subjected to the assessment of particles and the measurement of relative density and particle size distribution of a dissolution residue. The results are shown in Table 2.

### Comparative Example 1

A sputtering target was obtained in the same manner as Example 1 except for changing the mixing time using a shaking mixer having a three-dimensional motion mechanism for rotating in the vertical and horizontal directions to 15 minutes and was subjected to the assessment of particles and the measurement of relative density and particle size distribution of a dissolution residue. The results are shown in Table 2.

### Comparative Example 2

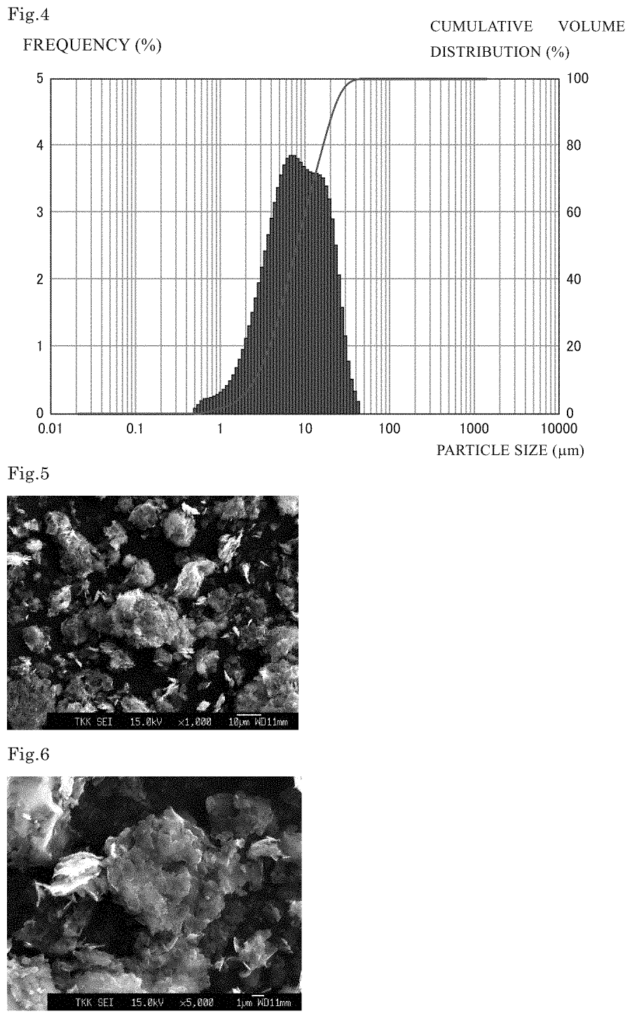

A sputtering target was obtained in the same manner as Example 1 except for: using a medium stirring mill with 4 kg of zirconia balls in place of the shaking mixer having a three-dimensional motion mechanism for rotating in the vertical and horizontal directions; and changing the mixing conditions to 300 rpm for 3 hours as well as the sintering temperature to 1,150° C. The obtained sputtering target was subjected to the assessment of particles and the measurement of relative density and particle size distribution of a dissolution residue. The results are shown in Table 2. FIG. 4 shows the measured particle size distribution of a dissolution residue, and FIGS. 5 and 6 show photographs of scanning electron microscope (SEM) (1,000× and 5,000×) of the dissolution residue.

### Comparative Example 3

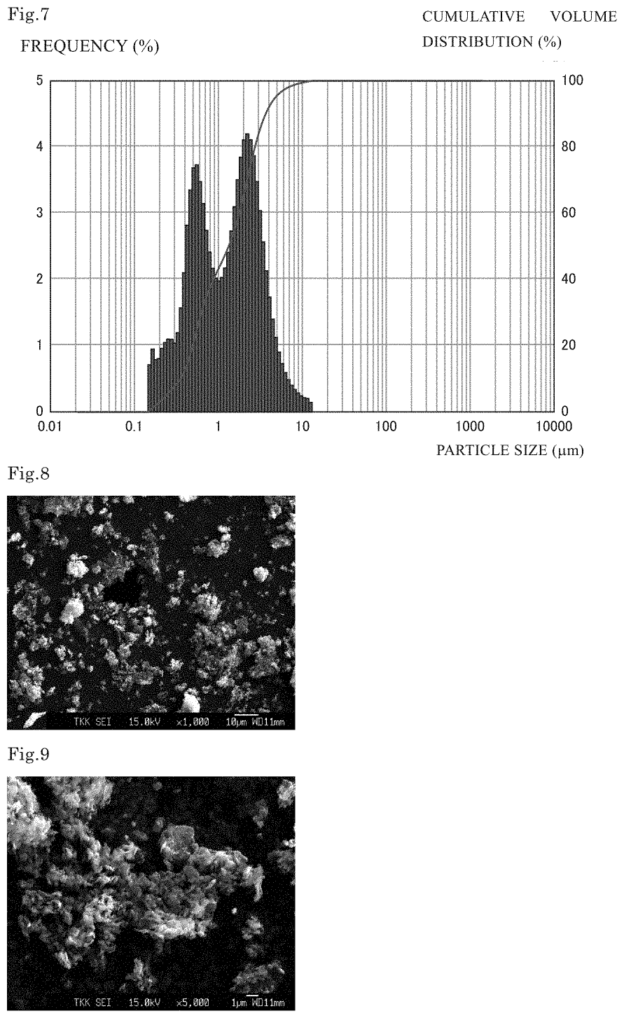

A sputtering target was obtained in the same manner as Comparative Example 2 except for changing the mixing conditions using the medium stirring mill to vigorous mixing at 462 rpm for 12 hours as well as the sintering temperature to 1,300° C. and was subjected to the assessment of particles and the measurement of relative density and particle size distribution of a dissolution residue. The results are shown in Table 2. FIG. 7 shows the measured particle size distribution of a dissolution residue, and FIGS. 8 and 9 show photographs of scanning electron microscope (SEM) (1,000× and 5,000×) of the dissolution residue.

TABLE 2
Conditions and Results

| | | | | | Sintering results | | | | | |
|---|---|---|---|---|---|---|---|---|---|---|
| | Sintering conditions | | | | | | | | | Less |
| | | | | Sintering | Relative | | | | | than |
| | Composition | Mixing | Mixing | temperature | density | Particle | D10 | D50 | D90 | 1 μm |
| | mol % | apparatus | conditions | (° C.) | (%) | count | (μm) | (μm) | (μm) | (%) |
| Ex. 1 | (Fe—50Pt)—40C | Shaking mixer | 32 rpm 48 h | 900 | 96.8 | 6 | 0.77 | 3.14 | 7.85 | 13.84 |
| Ex. 2 | (Fe—50Pt)—40C | Shaking mixer | 32 rpm 24 h | 900 | 96.8 | 11 | 1.93 | 5.85 | 14.63 | 3.80 |
| Ex. 3 | (Fe—50Pt)—40C | Shaking mixer | 32 rpm 48 h | 900 | 95.5 | 18 | 0.69 | 2.84 | 6.97 | 22.76 |
| Ex. 4 | (Fe—45Pt—10Ag)—40C | Shaking mixer | 32 rpm 48 h | 900 | 97.2 | 4 | 1.37 | 3.96 | 8.16 | 6.88 |
| Ex. 5 | (Fe—52Pt)—30C—6SiO₂ | Shaking mixer | 32 rpm 48 h | 900 | 95.9 | 23 | 0.71 | 3.26 | 10.25 | 15.69 |
| Ex. 6 | (Fe—45Pt)—30C—5BN | Shaking mixer | 32 rpm 48 h | 900 | 95.9 | 15 | 0.93 | 3.43 | 8.48 | 10.96 |
| Ex. 7 | (Co—5Cr—23Pt)—40C | Shaking mixer | 32 rpm 48 h | 900 | 93.8 | 13 | 1.94 | 4.23 | 8.25 | 1.54 |
| Ex. 8 | (Co—12Cr—18Pt)—20C | Shaking mixer | 32 rpm 48 h | 900 | 95.8 | 22 | 1.68 | 4.14 | 7.99 | 3.22 |
| Ex. 9 | (Fe—30Co—30Pt)—50C | Shaking mixer | 32 rpm 48 h | 900 | 96.0 | 18 | 0.89 | 3.33 | 8.35 | 11.22 |
| Comp. | (Fe—50Pt)—40C | Shaking mixer | 32 rpm 15 min | 900 | 97.1 | 101 | 5.22 | 19.64 | 49.68 | 0.00 |
| Ex. 1 | | | | | | | | | | |
| Comp. | (Fe—50Pt)—40C | Medium stirring | 300 rpm 3 h | 1,150 | 94.9 | 316 | 2.53 | 7.98 | 21.35 | 1.62 |
| Ex. 2 | | mill | | | | | | | | |
| Comp. | (Fe—50Pt)—40C | Medium stirring | 462 rpm 12 h | 1,300 | 95.8 | 404 | 0.35 | 1.33 | 3.66 | 43.14 |
| Ex. 3 | | mill | | | | | | | | |

[Particle Size Distribution of Dissolution Residue]

FIGS. 2, 3, 5, 6, 8, and 9 are SEM photographs, where dark portions are a double-sided tape used for attaching a dissolution residue to a jig for SEM observation, white portions are sharp angled parts of residue particles, and gray portions are residue particles. In Examples 1 to 8, D90 is more than 5 μm and less than 15 μm, D50 is more than 2 μm and less than 6 μm, D10 is more than 0.6 μm and less than 2 μm, and less than 1 μm particles are less than 23% in the cumulative volume distribution. FIG. 1 shows a homogenous distribution state close to a normal distribution. From FIGS. 2 and 3, an almost uniform particle size is observed without extremely fine particles or excessively aggregated particles. In contrast, in Comparative Example 1 in which a mixing time is short, the particle size distribution is shifted toward a larger size where D90 is about 50 μm, D50 is about 20 μm, D10 is about 5 μm, and less than 1 μm particles are 0% in the cumulative volume distribution. Comparative Example 2, in which mixing conditions are more vigorous than those of Comparative Example 1, exhibits a rather wide distribution state where D90 is about 21 μm, D50 is about 8 μm, D10 is about 2.5 μm, and 1 μm particles are 1.6% in the cumulative volume distribution. FIGS. 5 and 6 show the presence of particles in various sizes revealing non-uniform degree of pulverization. In Comparative Example 3 under vigorous mixing conditions, extremely fine particles predominate where D90 is about 3.6 pm, D50 is about 1.3 μm, D10 is about 0.3 μm, and less than 1 μm particles are 43% in the cumulative volume distribution. FIG. 7 shows a bimodal distribution state, and FIGS. 8 and 9 reveal coexistence of extremely fine particles and aggregates of fine particles. In Comparative Example 3, in which fine particles and aggregates of fine particles exist, the number of generated particles is the largest. Accordingly, it was confirmed that fine particles of less than 1 μm and aggregates considerably affect particle generation.

The comparison between Example 1 and Example 2, which are different in mixing time of raw material powder, reveals that the particle size of a dissolution residue tends to decrease as the mixing time is prolonged. Meanwhile, the comparison between Comparative Examples 2 and 3 reveals that a prolonged mixing time in a medium stirring mill results in extremely fine particles and reaggregation. Accordingly, it was confirmed that the mixing conditions employed in the production method of the present invention prevent formation of extremely fine particles and suppress reaggregation.

In comparison between Example 1 and Example 3, which are different in particle size of raw material C powder, Example 2 with a smaller particle size of C powder has the particle size distribution slightly shifted toward a smaller size relative to Example 1, but the effect is not significant.

[Particle Count]

The particle count for the sputtering targets of Examples 1 to 8 is extremely small of 23 or less, in contrast to 100 or more for Comparative Examples 1 to 3. Accordingly, it was confirmed that particle generation can be suppressed.

[Relative Density]

In comparison among Examples 1 to 3 and Comparative Examples 1 to 3 having the same composition, the relative densities of Examples 1 to 3 are 95.5% and 96.8%, which are lower than 97.1% of Comparative Example 1 but higher than 94.9% of Comparative Example 2. Accordingly, a relative density of 95% or more required for a sputtering target is considered to be achieved.

1. A C-containing sputtering target comprising Pt, C, and one or more selected from Fe and Co, wherein in a particle size distribution of a dissolution residue of the sputtering target, 90 percentile of the particle diameter based on the volume, D90 is 20.0 μm or less, and particle size of less than 1.0 μm accounts for 40% or less in cumulative volume distribution.

2. The C-containing sputtering target according to claim 1, wherein the D90 is 5.0 μm or more and 20.0 μm or less.

3. The C-containing sputtering target according to claim 1, wherein further in the particle size distribution of the dissolution residue of the sputtering target, 50 percentile of the particle diameter based on the volume, D50 is 2.0 μm or more and 7.0 μm or less.

4. The C-containing sputtering target according to claim 1, wherein further in the particle size distribution of the dissolution residue of the sputtering target, 10 percentile of the particle diameter based on the volume, D10 is 0.5 μm or more and 2.0 μm or less.

5. The C-containing sputtering target according to claim 1, comprising 5 mol % or more and 55 mol % or less of Pt and 10 mol % or more and 60 mol % or less of C, with the balance being one or more selected from Fe and Co as well as incidental impurities.

6. The C-containing sputtering target according to claim 1, comprising 5 mol % or more and 55 mol % or less of Pt and 10 mol % or more and 60 mol % or less of C, with the balance being one or more selected from Fe and Co as well as incidental impurities and further comprising, in total, more than 0 mol % and 20 mol % or less of one or more selected from Ag, Au, B, Cr, Cu, Ge, Ir, Ni, Pd, Rh, and Ru.

7. The C-containing sputtering target according to claim 1, comprising 5 mol % or more and 55 mol % or less of Pt and 10 mol % or more and 60 mol % or less of C, with the balance being one or more selected from Fe and Co as well as incidental impurities and further comprising, in total, more than 0 mol % and 20 mol % or less of a nonmagnetic material excluding C.

8. The C-containing sputtering target according to claim 7, wherein the nonmagnetic material is one or more selected from Si oxide, Ti oxide, Ta oxide; B nitride, Ti nitride, and Ta nitride.

9. A production method for a C-containing sputtering target comprising Pt, C, and one or more selected from Fe and Co, wherein in a particle size distribution of a dissolution residue of the sputtering target, 90 percentile of the particle diameter based on the volume, D90 is 20.0 μm or less, and particle size of less than 1.0 μm accounts for 40% or less in cumulative volume distribution, wherein the method comprises: mixing a C powder with at least one selected from metal powders and an alloy powder by a mixing apparatus having a three-dimensional motion mechanism for rotating in a vertical direction and a horizontal direction to prepare a mixture; and sintering the mixture.

10. The production method for the C-containing sputtering target according to

9. , wherein the mixing of a C powder with at least one selected from metal powders and an alloy powder is performed at 10 rpm or more and 50 rpm or less for 20 hours or more.

11. The C-containing sputtering target according to claim 1, comprising 5 mol % or more and 55 mol % or less of Pt and 10 mol % or more and 60 mol % or less of C, with the balance being one or more selected from Fe and Co as well as incidental impurities and further comprising, in total, more than 0 mol % and 20 mol % or less of one or more selected from Ag, Au, B, Cr, Cu, Ge, Ir, Ni, Pd, Rh, and Ru and further comprising, in total, more than 0 mol % and 20 mol % or less of a nonmagnetic material excluding C.

12. The C-containing sputtering target according to claim 11, wherein the nonmagnetic material is one or more selected from Si oxide, Ti oxide, Ta oxide; B nitride, Ti nitride, and Ta nitride.
